(19) United States
(12) Patent Application Publication
(10) Pub. No.: US 2022/0267563 A1
(43) Pub. Date: Aug. 25, 2022

(54) COMPOSITIONS CONTAINING THERMALLY CONDUCTIVE FILLERS

(71) Applicant: PPG Industries Ohio, Inc., Cleveland, OH (US)

(72) Inventors: Fabien Mezzanotti, Montesson (FR); Josiane Léon, Thiers sur Thève (FR); Liang Ma, Allison Park, PA (US); Allison G. Condie, Valencia, PA (US); Maria S. French, Canfield, OH (US)

(73) Assignee: PPG Industries Ohio, Inc., Cleveland, OH (US)

(21) Appl. No.: 17/627,664

(22) PCT Filed: Jul. 15, 2020
(86) PCT No.: PCT/US2020/042099

§ 371 Date: Jan. 15, 2022

(30) Foreign Application Priority Data
Jul. 16, 2019 (FR) 1908020

(51) Int. Cl. C08K 3/013; C08K 3/22; H01M 10/613; H01M 10/653; H05K 1/02; H05K 3/28

(52) U.S. Cl. CPC C08K 3/013; C08K 3/22; H01M 10/613; H01M 10/653; H05K 1/0209; H05K 3/285; C08K 2201/001; C08K 2003/2227

(57) ABSTRACT

The present invention is directed to a composition comprising a thermoplastic polymer and a thermally conductive filler package comprising thermally conductive, electrically insulative filler particles having a thermal conductivity of at least 5 W/m K (measured according to ASTM D7984) and a volume resistivity of at least 10 Ωm (measured according to ASTM D257, C611, or B 193) and being present in an amount of at least 50% by volume based on total volume of the filler package. The present invention also is directed to coatings comprising a thermal conductivity of at least 0.5 W/m·K (measured according to ASTM D7984) and to substrates, at least a portion of which is coated with such a coating.

### CROSS-REFERENCE TO RELATED APPLICATION

This application claims the benefit of French Patent Application No. 1908020, filed on Jul. 16, 2019, and entitled “Compositions Containing Thermally Conductive Fillers,” the entire content of which is incorporated herein by reference.

### FIELD OF THE INVENTION

The present invention relates to compositions containing a thermally conductive filler component, for example sealant compositions, adhesive compositions, 3D-printable compositions, and coating compositions.

### BACKGROUND OF THE INVENTION

Coating compositions, including sealants and adhesives, are utilized in a wide variety of applications to treat a variety of substrates or to bond together two or more substrate materials.

### SUMMARY OF THE INVENTION

The present invention is directed to compositions comprising: a thermoplastic polymer; and a thermally conductive filler package comprising thermally conductive, electrically insulative filler particles having a thermal conductivity of at least 5 W/m·K (measured according to ASTM D7984) and a volume resistivity of at least 10 Ω·m (measured according to ASTM D257, C611, or B193) and being present in an amount of at least 50% by volume based on total volume of the filler package.

The present invention also is directed to a coating, comprising a thermal conductivity of at least 0.5 W/m·K (measured according to ASTM D7984) and a leakage current of less than 0.5 mA/mm² (measured according to IEC 60243).

The present invention also is directed to a substrate comprising a surface, at least a portion of which is coated with a composition of the present invention.

The present invention also is directed to a battery assembly comprising a substrate of the present invention.

The present invention also is directed to a circuit board comprising a substrate of the present invention.

The present invention also is directed to a part comprising a substrate of the present invention.

The present invention also is directed to an article comprising a substrate of the present invention.

The present invention also is directed to a method of forming a coating on a substrate surface comprising: applying a composition of the present invention to a surface of the substrate such that at least a portion of the surface is coated with the composition.

The present invention also is directed to a method of forming an article comprising extruding a composition of the present invention.

The present invention also is directed to an article formed by a method of extruding a composition of the present invention.

### BRIEF DESCRIPTION OF THE DRAWINGS

FIG. 1 is a schematic perspective view illustrating a thermally conductive member utilized in a battery assembly.

### DETAILED DESCRIPTION OF THE INVENTION

For purposes of this detailed description, it is to be understood that the invention may assume alternative variations and step sequences, except where expressly specified to the contrary. Moreover, other than in any operating examples, or where otherwise indicated, all numbers expressing, for example, quantities of ingredients used in the specification and claims are to be understood as being modified in all instances by the term “about”. Accordingly, unless indicated to the contrary, the numerical parameters set forth in the following specification and attached claims are approximations that may vary depending upon the desired properties to be obtained by the present invention. At the very least, and not as an attempt to limit the application of the doctrine of equivalents to the scope of the claims, each numerical parameter should at least be construed in light of the number of reported significant digits and by applying ordinary rounding techniques.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard variation found in their respective testing measurements.

Also, it should be understood that any numerical range recited herein is intended to include all sub-ranges subsumed therein. For example, a range of “1 to 10” is intended to include all sub-ranges between (and including) the recited minimum value of 1 and the recited maximum value of 10, that is, having a minimum value equal to or greater than 1 and a maximum value of equal to or less than 10.

As used herein, “including,” “containing” and like terms are understood in the context of this application to be synonymous with “comprising” and are therefore open-ended and do not exclude the presence of additional undescribed or unrecited elements, materials, ingredients or method steps. As used herein, “consisting of” is understood in the context of this application to exclude the presence of any unspecified element, ingredient or method step. As used herein, “consisting essentially of” is understood in the context of this application to include the specified elements, materials, ingredients or method steps “and those that do not materially affect the basic and novel characteristic(s)” of what is being described.

In this application, the use of the singular includes the plural and plural encompasses singular, unless specifically stated otherwise. For example, although reference is made herein to “a” thermoplastic polymer or “a” filler material, a combination (i.e., a plurality) of these components may be used.

In addition, in this application, the use of “or” means “and/or” unless specifically stated otherwise, even though “and/or” may be explicitly used in certain instances.

As used herein, the terms “on,” “onto,” “applied on,” “applied onto,” “formed on,” “deposited on,” “deposited onto,” and the like mean formed, overlaid, deposited, or provided on, but not necessarily in contact with, a substrate surface. For example, a composition “applied onto” a substrate surface does not preclude the presence of one or more other intervening coating layers or films of the same or different composition located between the composition and the substrate surface.

As used herein, a “coating composition” refers to a composition, e.g., a mixture or a dispersion, that is capable of producing a film, layer, or the like on at least a portion of a substrate surface.

As used herein, a “sealant composition” refers to a coating composition, e.g., a mixture or a dispersion, that has the ability to resist atmospheric conditions and particulate matter, such as moisture and temperature and at least partially block the transmission of materials, such as particulates, water, fuel, and/or other liquids and gasses.

As used herein, a “gap filler composition” refers to a coating composition, e.g., a mixture or a dispersion, that fills a gap between thermal transfer surfaces in order to increase thermal transfer efficiency as compared to having the gap filled with air.

As used herein, an “adhesive composition” refers to a coating composition, e.g., a mixture or a dispersion, that forms a bond with a substrate when pressure is applied to the composition. Once applied, the composition resists flow. The initial bond strength upon contact can be measured as tack according to ASTM D-3121.

As used herein, the term “thermoplastic” refers to a component that can soften upon heating and solidify upon cooling and does not need to react with other components of a composition in order to function but that is present as a blended ingredient, i.e., does not form a thermoset material.

As used herein, the term “thermoplastic elastomer” refers to a class of polymers that can be stretched repeatedly to at least twice their original length at room temperature with an ability to return to their approximate original length when the stress is released. In addition, these polymers can be softened or melted when heated and hardened when cooled.

As used herein, the term “one component” or “1K” refers to a composition in which all of the ingredients may be premixed and stored and do not readily react at ambient or slightly thermal conditions and remain “workable” for at least 10 days after mixing. As further defined herein, ambient conditions generally refer to room temperature and humidity conditions or temperature and humidity conditions that are typically found in the area in which the composition is applied to a substrate, e.g., at 20° C. to 40° C. and 20% to 80% relative humidity, while slightly thermal conditions are temperatures that are slightly above ambient temperature. As used herein, the term “workable” means that the composition is of a viscosity that it is able to be deformed and/or shaped under manual pressure and may have a viscosity less than such viscosity.

As used herein, the term “thermally conductive filler” or “TC filler” means a pigment, filler, or inorganic powder that has a thermal conductivity of at least 5 W/m·K at 25° C. (measured according to ASTM D7984).

As used herein, the term “non-thermally conductive filler” or “NTC filler” means a pigment, filler, or inorganic powder that has a thermal conductivity of less than 5 W/m·K at 25° C. (measured according to ASTM D7984).

As used herein, the term “electrically insulative filler” or “EI filler” means a pigment, filler, or inorganic powder that has a volume resistivity of at least 1 m (measured according to ASTM D257, C611, or B193).

As used herein, the term “electrically conductive filler” or “EC filler” means a pigment, filler, or inorganic powder that has a volume resistivity of less than 1 m (measured according to ASTM D257, C611, or B193).

As used herein, the term “thermally conductive filler package” means a plurality of filler particles comprising at least one type of thermally conductive, electrically insulative filler particles and optionally at least one type of thermally conductive, electrically conductive filler particles and/or at least one type of non-thermally conductive, electrically insulative filler particles. For clarity, the term “filler package” excludes any ingredients that are not TC/EI filler particles, TC/EC filler particles, and/or NTC/EI filler particles.

As used herein, the term “solvent” refers to a molecule or a compound that has a high vapor pressure such as greater than 2 mm Hg at 25° C. determined by differential scanning calorimetry according to ASTM E1782 and is used to lower the viscosity of a resin but that does not have a reactive functional group capable of reacting with a functional group(s) on molecules or compounds in a composition.

As used herein, the term “plasticizer” refers to a molecule or a compound that has a low vapor pressure such no greater than 2 mm Hg at 25° C. determined by differential scanning calorimetry according to ASTM E1782 and does not have a functional group capable of reacting with a functional group(s) on molecules or compounds in a composition and that is added to the composition to decrease viscosity, decrease glass transition temperature (Tg), and impart flexibility.

As used herein, the volume percentage of each ingredient is calculated using the below equation:

Vol % (ingredient)=(volume of ingredient/total volume of composition)×100%,

where the volume of ingredient=(mass of ingredient/true density of ingredient).

The present invention is directed to a one-component composition comprising, or consisting essentially of, or consisting of, a thermoplastic polymer; and a thermally conductive filler package comprising thermally conductive, electrically insulative filler particles having a thermal conductivity of at least 5 W/m·K (measured according to ASTM D7984) and a volume resistivity of at least 10 m (measured according to ASTM D257, C611, or B193) and being present in an amount of at least 50% by volume based on total volume of the filler package. As used herein, the composition “consists essentially of” a thermoplastic polymer and a thermally conductive filler package means that the thermal conductivity and the leakage current of the coating composition is achieved by the thermoplastic polymer and the thermally conductive filler package, and that any other ingredients present in the composition do not materially affect these properties.

The composition may be a one-component coating composition, such as a sealant composition, an adhesive composition, a gap filling composition, a putty, a molding compound, a potting compound, and/or a 3D-printable composition or may be used to form a film, layer, or the like, or a part, such as a casted, molded, extruded, or machined part.

As stated above, the composition comprises a thermoplastic polymer. The thermoplastic polymer may be a homopolymer or a copolymer, such as a block copolymer, a random copolymer, a terpolymer, or combinations thereof. The thermoplastic may be a thermoplastic elastomer. The thermoplastic polymer optionally may be synthetic or natural. Suitable thermoplastic polymers useful in the present invention include polyamides, such as nylon and aramid; polyolefins, such as polybutadiene, polyisobutylene, polybutene, polymethylpentene, amorphous polypropylene, polyethylene terephthalate, polyethylene, polystyrene, ethylene propylene copolymer, polyvinyl chloride, and vinyl chloride copolymer; polyurethanes; styrene block copolymers, such as styrene-butadiene, styrene-isoprene, styrene-butadiene-styrene, styrene-isoprene-styrene, styrene-ethylene/butylene-styrene, styrene-ethylene/propylene; polyethers such as polyethylene oxide, polypropylene oxide, polyoxymethylene, polyp-phenylene ether); ethylene-vinylacetate; polybenzimidazole; polyphenylene sulfide; polyether sulfone; polyether ether ketone; chloroprene; acrylonitrile butadiene; polycarbonate; polyacrylates such as poly(meth)acrylate; or combinations thereof. In examples, useful non-reactive elastomers include Polyvest® polybutadiene available from Evonik. Examples of reactive elastomers include Hypro® ATBN amine-functional butadiene copolymer available from Emerald Performance Materials. As used herein, the term “block copolymer” refers to a copolymer formed when the two monomers cluster together and form blocks of repeating units. As used herein, the term “random copolymer” refers to a copolymer comprised of more than one kind of repeating unit, in which there is a random distribution of repeating units. As used herein, the term “terpolytner” refers to a polymer that results from copolymerization of three discrete monomers. As used herein, a “thermoplastic elastomer” refers to a copolymer having both thermoplastic and elastomeric properties. Suitable examples of thermoplastic elastomers include olefinic thermoplastic elastomers, polyether block amides polybutadiene thermoplastics elastomer, polyester thermoplastic elastomer, styreneic thermoplastic elastomer, and vinyl thermoplastic elastomers, and rubbers such as butadiene rubber, butyl rubber, bromobutyl rubber, chlorobutyl rubber, polyisobutylene rubber, chlorosuflonated polyethylene rubber, epichlorohydrin rubber, ethylene-propylene rubber, fluoroelastomoer (vinylidene fluoride-hexafluoropropylene copolymer), natural rubber, neoprene rubber, nitrile rubber, polysulfide rubber, polyurethane rubber, silicone rubber, styrene-butadiene rubber.

Optionally, the thermoplastic polymer may be substantially free, or essentially free, or completely free, of polyester. As used herein with respect to the absence of polyester in the thermoplastic polymer, “substantially free” means that polyester is present, if at all, in an amount of less than 3% by volume based on total volume of the composition. As used herein with respect to the absence of polyester in the thermoplastic polymer, “essentially free” means that polyester is present, if at all, in an amount of less than 1% by volume based on total volume of the composition. As used herein with respect to the absence of polyester in the thermoplastic polymer, “complete free” means that polyester is present, if at all, in an amount of less than 0.1% by volume based on total volume of the composition.

Optionally, the thermoplastic polymer may be substantially free, or essentially free, or completely free, of silicone. As used herein with respect to the absence of silicone in the thermoplastic polymer, “substantially free” means that silicone is present, if at all, in an amount of less than 3% by volume based on total volume of the composition. As used herein with respect to the absence of silicone in the thermoplastic polymer, “essentially free” means that silicone is present, if at all, in an amount of less than 1% by volume based on total volume of the composition. As used herein with respect to the absence of silicone in the thermoplastic polymer, “complete free” means that silicone is present, if at all, in an amount of less than 0.1% by weight based on total volume of the composition.

The thermoplastic polymer may be substantially free or completely free, of reactive functional groups, that is, functional groups that react with other functional groups in the composition. As used herein, the term “substantially free” with respect to the presence of a reactive functional group on the thermoplastic polymer means that less than one reactive functional group is present on the thermoplastic polymer. As used herein, the term “completely free” with respect to the presence of a reactive functional group means that there are 0 reactive functional groups present on the thermoplastic polymer.

The thermoplastic polymer may be present in the composition in an amount of at least 1% by volume based on total volume of the composition, such as at least 10% by volume, such as at least 20% by volume, such as at least 30% by volume, and may be present in the composition in an amount of no more than 80% by volume based on total volume of the composition, such as no more than 70% by volume, such as no more than 60% by volume, such as no more than 40% by volume. The thermoplastic polymer may be present in the composition in an amount of 1% by volume to 80% by volume based on total volume of the composition, such as 10% by volume to 70% by volume, such as 20% by volume to 60% by volume, such as 30% by volume to 40% by volume.

The present invention also may comprise a thermally conductive filler package comprising particles of a thermally conductive, electrically insulative filler material (referred to herein as “TC/EI filler material” and described in more detail below). The TC/EI filler material may comprise organic or inorganic material and may comprise particles of a single type of filler material or may comprise a particles of two or more types of TC/EI filler materials. That is, the thermally conductive filler package may comprise particles of a first TC/EI filler material and may further comprise particles of at least a second (i.e., a second, a third, a fourth, etc.) TC/EI filler material that is different from the first TC/EI filler material. In an example, the particles of the first TC/EI filler material may have an average particle size that is at least one order of magnitude greater than an average particle size of the particles of the second TC/EI filler material, such as at least two orders of magnitude greater, such as at least three orders of magnitude greater, wherein the particle sizes may be measured, for example, using a SEM as described above. As used herein with respect to types of filler material, reference to “first,” “second”, etc. is for convenience only and does not refer to order of addition to the filler package or the like.

Optionally, as discussed in more detail below, the filler package also may comprise particles of thermally conductive, electrically conductive filler material (referred to herein as “TC/EC” filler material) and/or particles of non-thermally conductive, electrically insulative filler material (referred to herein as “NTC/EI” filler material). The filler materials may be organic or inorganic.

The TC/EC filler material may comprise particles of a single type of filler material or may comprise particles of two or more types of thermally conductive, electrically conductive filler materials. That is, the thermally conductive filler package may comprise particles of a first TC/EC filler material and may further comprise particles of at least a second (i.e., a second, a third, a fourth, etc.) TC/EC filler material that is different from the first TC/EC filler material. In an example, the particles of the first TC/EC filler material may have an average particle size that is at least one order of magnitude greater than an average particle size of the particles of the second TC/EC filler material, such as at least two orders of magnitude greater, such as at least three orders of magnitude greater, wherein the particle sizes may be measured, for example, using a SEM as described above.

Likewise, the NTC/EI filler material may comprise particles of a single type of filler material or may comprise a particles of two or more types of NTC/EI filler materials. That is, the thermally conductive filler package may comprise particles of a first NTC/EI filler material and may further comprise particles of at least a second (i.e., a second, a third, a fourth, etc.) NTC/EI filler material that is different from the first NTC/EI filler material. In an example, the particles of the first NTC/EI filler material may have an average particle size that is at least one order of magnitude greater than an average particle size of the particles of the second NTC/EI filler material, such as at least two orders of magnitude greater, such as at least three orders of magnitude greater, wherein the particle sizes may be measured, for example, using a SEM as described above.

Particles of filler material used in the thermally conductive filler package may have a reported Mohs hardness of at least 1 (based on the Mohs Hardness Scale) measured according to ASTM D2240 or ASTM C1895-20, such as at least 2, such as at least 3, and may have a reported Mohs hardness of no more than 10, such as no more than 8, such as no more than 7. Particles of filler material used in the thermally conductive filler package may have a reported Mohs hardness of 1 to 10, such as 2 to 8, such as 3 to 7.

Particles of filler material used in the thermally conductive filler package may have a reported average particle size in at least one dimension of at least 0.01 μm, as reported by the manufacturer, such as at least 2 μm, such as at least 10 μm, and may have a reported average particle size in at least one dimension of no more than 500 μm as reported by the manufacturer, such as no more than 400 μm, such as no more than 300 μm, such as no more than 100 μm. The particles of filler material used in the thermally conductive filler package may have a reported average particle size in at least one dimension of 0.01 μm to 500 μm as reported by the manufacturer, such as 0.1 μm to 400 μm, such as 2 μm to 300 μm, such as 10 μm to 100 μm. Suitable methods of measuring average particle size include measurement using an instrument such as the Quanta 250 FEG SEM or an equivalent instrument.

Particles of filler material used in the thermally conductive filler package may comprise a plurality of particles each having, for example, a platy, spherical, or modular shape, and agglomerates thereof.

Particles of filler material used in the thermally conductive filler package may be thermally conductive. The particles of thermally conductive filler material may have a thermal conductivity of at least 5 W/m·K at 25° C. (measured according to ASTM D7984), such as at least 18 W/m·K, such as at least 55 W/m·K, and may have a thermal conductivity of no more than 3,000 W/m·K at 25° C., such as no more than 1,400 W/m·K, such as no more than 450 W/m·K. The particles of a thermally conductive filler material may have a thermal conductivity of 5 W/m·K to 3,000 W/m·K at 25° C. (measured according to ASTM D7984), such as 18 W/m·K to 1,400 W/m·K, such as 55 W/m·K to 450 W/m·K.

Particles of filler material used in the thermally conductive filler package may be non-thermally conductive. The particles of non-thermally conductive filler material may have a thermal conductivity of less than 5 W/m·K at 25° C. (measured according to ASTM D7984), such as no more than 3 W/m·K, such as no more than 1 W/m·K, such as no more than 0.1 W/m·K, such as no more than 0.05 W/m·K. Thermal conductivity may be measured as described above.

Particles of filler material used in the thermally conductive filler package may be electrically insulative. The particles of electrically insulative filler material may have a volume resistivity of at least 1 Ω·m (measured according to ASTM D257, C611, or B193), such as at least 10 Ω·m, such as at least 100 Ω·m.

Particles of filler material used in the thermally conductive filler package may be electrically conductive. The particles of electrically conductive filler material may have a volume resistivity of less than 1 Ω·m (measured according to ASTM D257, C611, or B193), such as less than 0.1 Ω·m.

The filler package may be present in the composition in an amount of at least 20% by volume based on total volume of the composition, such as at least 30% by volume, such as at least 40% by volume, such as at least 50% by volume, and may be present in the composition in an amount of no more than 99% by volume based on total volume of the composition, such as no more than 90% by volume, such as no more than 80% by volume, such as no more than 70% by volume. The thermally conductive filler package may be present in the composition in an amount of 20% by volume to 99% by volume based on total volume of the composition, such as 30% by volume to 90% by volume, such as 40% by volume to 80% by volume, such as 50% by volume to 70% by volume.

As noted above, the thermally conductive filler package may comprise particles of TC/EI filler material.

Suitable TC/EI filler materials include boron nitride (for example, commercially available as CarboTherm from Saint-Gobain, as CoolFlow and PolarTherm from Momentive, and as hexagonal boron nitride powder available from Panadyne), silicon nitride, or aluminum nitride (for example, commercially available as aluminum nitride powder available from Micron Metals Inc., and as Toyalnite from Toyal), boron arsenide, metal oxides such as aluminum oxide (for example, commercially available as Microgrit from Micro Abrasives, as Nabalox from Nabaltec, as Aeroxide from Evonik, and as Alodur from Imerys), magnesium oxide, beryllium oxide, silicon dioxide, titanium oxide, zinc oxide, nickel oxide, copper oxide, or tin oxide, metal hydroxides such as aluminum trihydrate, aluminum hydroxide or magnesium hydroxide, arsenides such as boron arsenide, carbides such as silicon carbide, minerals such as agate and emery, ceramics such as ceramic microspheres (for example, commercially available from Zeeospheres Ceramics or 3M), silicon carbide, and diamond. These fillers can also be surface modified, such as PYROKISUMA 5301K available from Kyowa Chemical Industry Co., Ltd. These thermally conductive fillers may be used alone or in a combination of two or more.

The TC/EI filler particles may be present in an amount of at least 50% by volume based on total volume of the filler package, such as at least 60% by volume, such as at least 70% by volume, such as at least 80% by volume, such as at least 90% by volume, and may be present in an amount of no more than 100% by volume based on total volume of the filler package, such as no more than 90% by volume, such as no more than 80% by volume. The TC/EI filler particles may be present in an amount of 50% by volume to 100% by volume based on total volume of the filler package, such as 60% by volume to 100% by volume, such as 70% by volume to 100% by volume, such as 80% by volume to 100% by volume, such as 90% by volume to 100% by volume, such as 50% by volume to 90% by volume, such as 60% by volume to 90% by volume, such as 70% by volume to 90% by volume, such as 80% by volume to 90% by volume, such as such as 50% by volume to 80% by volume, such as 60% by volume to 80% by volume, such as 70% by volume to 80% by volume.

The filler package may comprise thermally stable filler materials. In an example, at least a portion of the TC/EI filler particles may be thermally stable. In an example, the composition may comprise at least a portion of TC/EI filler particles that are thermally unstable.

Suitable thermally stable TC/EI filler materials include boron nitride (for example, commercially available as CarboTherm from Saint-Gobain, as CoolFlow and PolarTherm from Momentive, and as hexagonal boron nitride powder available from Panadyne), silicon nitride, or aluminum nitride (for example, commercially available as aluminum nitride powder available from Micron Metals Inc., and as Toyalnite from Toyal), boron arsenide, metal oxides such as aluminum oxide (for example, commercially available as Microgrit from Micro Abrasives, as Nabalox from Nabaltec, as Aeroxide from Evonik, and as Alodur from Imerys), magnesium oxide, beryllium oxide, silicon dioxide, titanium oxide, zinc oxide, nickel oxide, copper oxide, or tin oxide, carbides such as silicon carbide, minerals such as agate and emery, ceramics such as ceramic microspheres (for example, commercially available from Zeeospheres Ceramics or 3M), silicon carbide, and diamond. Arsenides such as boron arsenide. These fillers can also be surface modified, such as PYROKISUMA 5301K available from Kyowa Chemical Industry Co., Ltd. These thermally conductive fillers may be used alone or in a combination of two or more.

Suitable thermally unstable TC/EI filler materials include metal hydroxides such as aluminum trihydrate, aluminum hydroxide or magnesium hydroxide. These fillers can also be surface modified, such as Hymod®M9400 SF available from J.M. Huber Corporation. These thermally conductive fillers may be used alone or in a combination of two or more.

As noted above, the thermally conductive filler package may comprise particles of TC/EC filler material.

Suitable TC/EC filler materials include metals such as silver, zinc, copper, gold, or metal coated hollow particles. Carbon compounds such as, graphite (such as Timrex commercially available from Imerys or ThermoCarb commercially available from Asbury Carbons), carbon black (for example, commercially available as Vulcan from Cabot Corporation), carbon fibers (for example, commercially available as milled carbon fiber from Zoltek), graphene and graphenic carbon particles (for example, xGnP graphene nanoplatelets commercially available from XG Sciences, and/or for example, the graphene particles described below), carbonyl iron, copper (such as spheroidal powder commercially available from Sigma Aldrich), zinc (such as Ultrapure commercially available from Purity Zinc Metals and Zinc Dust XL and XLP available from US Zinc), and the like. Examples of “graphenic carbon particles” include carbon particles having structures comprising one or more layers of one-atom-thick planar sheets of sp2-bonded carbon atoms that are densely packed in a honeycomb crystal lattice. The average number of stacked layers may be less than 100, for example, less than 50. The average number of stacked layers may be 30 or less, such as 20 or less, such as 10 or less, such as 5 or less. The graphenic carbon particles may be substantially flat; however, at least a portion of the planar sheets may be substantially curved, curled, creased, or buckled. The particles typically do not have a spheroidal or equiaxed morphology. Suitable graphenic carbon particles are described in U.S. Publication No. 2012/0129980, at paragraphs [0059]-[0065], the cited portion of which is incorporated herein by reference. Other suitable graphenic carbon particles are described in U.S. Pat. No. 9,562,175, at 6:6 to 9:52, the cited portion of which are incorporated herein by reference.

The TC/EC filler particles, if present at all, may be present in an amount of no more than 50% by volume based on total volume of the filler package, such as no more than 40% by volume, such as no more than 30% by volume, such as no more than 20% by volume, such as no more than 10% by volume, and may be present in an amount of at least 0.1% by volume based on total volume of the filler package, such as at least 0.5% by volume, such as at least 1% by volume, such as at last 5% by volume, such as at least 10% by volume. The TC/EC filler particles may be present in an amount of 0.1% by volume to 50% by volume based on total volume of the filler package, such as 0.1% by volume to 40% by volume, such as 0.1% by volume to 30% by volume, such as 0.1% by volume to 20% by volume, such as 0.1% by volume to 10% by volume, such as 0.5% by volume to 50% by volume, such as 0.5% by volume to 40% by volume, such as 0.5% by volume to 30% by volume, such as 0.5% by volume to 20% by volume, such as 0.5% by volume to 10% by volume, such as 1% by volume to 50% by volume, such as 1% by volume to 40% by volume, such as 1% by volume to 30% by volume, such as 1% by volume to 20% by volume, such as 1% by volume to 10% by volume, such as 5% by volume to 50% by volume, such as 5% by volume to 40% by volume, such as 5% by volume to 30% by volume, such as 5% by volume to 20% by volume, such as 5% by volume to 10% by volume, such as 10% by volume to 50% by volume, such as 10% by volume to 40% by volume, such as 10% by volume to 30% by volume, such as 10% by volume to 20% by volume.

As noted above, the thermally conductive filler package may comprise particles of NTC/EI filler material.

Suitable NTC/EI filler materials include but are not limited to mica, silica, wollastonite, calcium carbonate, glass microspheres, clay such as kaloin, or combinations thereof.

As used herein, the term “mica” generally refers to sheet silicate (phyllosilicate) minerals. The mica may comprise muscovite mica. Muscovite mica comprises a phyllosilicate mineral of aluminum and potassium with the formula KAl₂(AlSi₃O₁₀)(F,OH)₂ or (KF)₂(Al₂O₃)₃(SiO₂)₆(H₂O). Exemplary non-limiting commercially available muscovite mica include products sold under the trade name DakotaPURE™, such as DakotaPURE™ 700, DakotaPURE™ 1500, DakotaPURE™ 2400, DakotaPURE™ 3000, DakotaPURE™ 3500 and DakotaPURE™ 4000, available from Pacer Minerals.

The silica (SiO₂) may comprise fumed silica which comprises silica that has been treated with a flame to form a three-dimensional structure. The fumed silica may be untreated or surface treated with a siloxane, such as, for example, polydimethylsiloxane. Exemplary non-limiting commercially available fumed silica includes products solder under the trade name AEROSIL®, such as AEROSIL® R 104, AEROSIL® R 106, AEROSIL® R 202, AEROSIL® R 208, AEROSIL® R 972 commercially available from Evonik Industries and products sold under the trade name HDK® such as HDK® H17 and HDK® H18 commercially available from Wacker Chemie AG.

Wollastonite comprises a calcium inosilicate mineral (CaSiO₃) that may contain small amounts of iron, aluminum, magnesium, manganese, titanium and/or potassium. The wollastonite may have a B.E.T. surface area of 1.5 to 2.1 m²/g, such as 1.8 m²/g and a median particle size of 6 microns to 10 microns, such as 8 microns. Non-limiting examples of commercially available wollastonite include NYAD 400 available from NYCO Minerals, Inc.

The calcium carbonate (CaCO₃) may comprise a precipitated calcium carbonate or a ground calcium carbonate. The calcium carbonate may or may not be surface treated with stearic acid. Non-limiting examples of commercially available precipitated calcium carbonate include Ultra-Pflex®, Albafil®, and Albacar HO® available from Specialty Minerals and Winnofil® SPT available from Solvay. Non-limiting examples of commercially available ground calcium carbonate include Duramite™ available from IMERYS and Marblewhite® available from Specialty Minerals.

Useful clay minerals include a non-ionic platy filler such as talc, pyrophyllite, chlorite, vermiculite, or combinations thereof.

The glass microspheres may be hollow borosilicate glass. Non-limiting examples of commercially available glass microspheres include 3M Glass bubbles type VS, K series, and S series available from 3M.

The NTC/EI filler particles, if present at all, may be present in an amount of no more than 10% by volume based on total volume of the filler package, such as no more than 5% by volume, such as no more than 1% by volume, and may be present in an amount of at least 0.1% by volume based on total volume of the filler package. The NTC/EI filler particles may be present in an amount of 0.1% by volume to 10% by volume based on total volume of the filler package, such as 0.5% by volume to 5% by volume, such as 0.5% by volume to 1% by volume.

Optionally, at least one of the thermally conductive fillers of the filler package may be comprise a surface treatment.

The thermally conductive filler may comprise a plurality of particles each having, for example, a platy, spherical, or modular shape, and agglomerates thereof.

The composition may further comprise a dispersant. As used herein, the term “dispersant” refers to a substance that may be added to the composition in order to improve the wettability of the particles, reduce surface tension between two phases, and/or improve separation and/or stabilization of the thermally conductive filler particles.

Useful dispersants may be anionic, cationic, amphoteric, or nonionic. Suitable dispersants for use in the composition include fatty acid, phosphoric acid esters, polyurethanes, polyamines, polyacrylates, polyalkoxylates, sulfonates, polyethers, and polyesters, or any combination thereof. Non-limiting examples of commercially available dispersants include ANTI-TERRA-U100, DISPERBYK-102, DISPERBYK-103, DISPERBYK-111, DISPERBYK-171, DISPERBYK-2151, DISPERBYK-2059, DISPERBYK-2000, DISPERBYK-2117, and DISPERBYK-2118 available from BYK Company; and SOLSPERSE 24000SC, SOLSPERSE 16000 and SOLSPERSE 8000 hyperdispersants available from The Lubrizol Corporation. Other suitable dispersants include Triton™ X-100, nonoxynol-9, polysorbate, Span®, poloxamers, Tergitol™, Antarox®, PENTEX® 99, PFOS, Calsoft®, Texapon®, Darvan®, cetyl trimethylammonium bromide (CTAB) and cetyl trimethylammonium chloride (CTAC), Cetylpyridinium chloride (CPC), Benzethonium chloride (BZT).

The dispersant, if present at all, may be present in the composition in an amount of no more than 20%% by volume based on total volume of the composition, such as no more than 10% by volume, and may be present, if at all, in the composition in an amount of at least 0.05% by volume based on total volume of the composition, such as at least 0.2% by volume, such as at least 1% by volume. The dispersant, if present at all, may be present in the composition in an amount of 0.05% by volume to 20% by volume based on total volume of the composition, such as 0.05% by volume to 10% by volume, such as 1% by volume to 10% by volume.

The composition may optionally comprise thixotropes, colorants, tints, plasticizers, solvents, adhesion promoters, tackifiers, antioxidants, water scavengers, moisture barriers, oils, defoamers, and/or rust inhibitors, collectively referred to herein as “Additives”.

Additives, if present at all, may be present in the composition in a total amount of no more than 30% by volume based on total volume of the composition, such as no more than 20% by volume, such as no more than 10% by volume, and may be present, if at all, in an amount of at least 0.01% by volume based on total volume of the composition, such as at least 0.02% by volume, such as at least 0.03% by volume. Additives, if present at all, may be present in the composition in an amount of 0.01% by volume to 30% by volume based on total volume of the composition, such as 0.02% by volume to 20% by volume, such as 0.03% by volume to 10% by volume.

Useful thixotropes that may be used include wax and organoclay. As used herein, “wax” refers to an organic substance which is solid at ambient conditions and forms a liquid when heated. Waxes useful in the present invention are not particularly limited provided the wax has properties suitable for obtaining the hot melt adhesive of the present invention. Generally, the wax may have a weight-average molecular weight of less than 10,000. Examples of suitable waxes useful in the present invention include microcrystalline waxes, polyethylene waxes, Fischer-Tropsch waxes, paraffin waxes, Castor wax, polypropylene waxes, amide derivatives of the former, or combinations thereof.

Useful colorants or tints may include phthalocyanine blue and Bleu Ultramarie.

As used herein, “tackifier” refers to a molecule or a compound that does not have a functional group capable of reacting with a functional group(s) on molecules or compounds in a composition and that is added to the composition to increase tack and adhesiveness. Useful tackifiers that may be used include rosin resins, terpene resins, and hydrocarbon resins. Examples of rosin resins include gum rosin, wood rosin, tall oil rosin, abietic acid type rosin, pimaric acid type rosin, hydrogenated rosin, rosin esters such as the Foral, Foralyn, and Staybelite available from Eastman. Examples of hydrocarbon resins include trans-1,3-pentadiene, cis-1,3-pentadiene, 2-methyl-2-butene, dicyclopentadiene, cyclopentadiene, cyclopentene, vinyl toluene, indene, α-methyl styrene, styrene, and methyl indene such as the Regalite available from Eastman. Examples or terpenes include limonene or the Sylvares available from Kraton.

Useful plasticizers that may be used include polymers, trimellitates, sebaceates, esters, phthalates, citrates, adipates benzoates, and the like. Non-limiting examples of such plasticizers include diisononylphthalate (Jayflex™ DINP available from Exxon Mobil), dioctylphthalate (Cereplas DOA™ available from Valtris), diisodecylphthalate (Jayflex™ DIDP available from Exxon Mobil), and alkyl benzyl phthalate (Santicizer 278 available from Valtris); benzoate-based plasticizers such as dipropylene glycol dibenzoate (K-Flex® available from Emerald Performance Materials); and other plasticizers including terephthalate-based dioctyl terephthalate (DEHT available from Eastman Chemical Company), alkylsulfonic acid ester of phenol (Mesamoll available from Borchers), epoxidized soybean oil (Plaschek 775 from Valtris), citric acid esters (Citroflex available from Morflex), phenylphophastes (Santicizer 148 from Solutia), and 1,2-cyclohexane dicarboxylic acid diisononyl ester (Hexamoll DINCH available from BASF).

Stabilizers may be blended to prevent reduction of molecular weight by heating, gelation, coloration, generation of an odor and the like in the hot melt adhesive to improve the stability of the hot melt adhesive. Stabilizers that may be used in the present invention are not particularly limited. Examples of stabilizers useful in the present invention include an antioxidant, an ultraviolet absorbing agent, or combinations thereof. The stabilizer optionally may be lactone-based. The antioxidant may be used to prevent oxidative degradation of the composition of the present invention. Examples of the antioxidant include phenol-based antioxidants, sulfur-based antioxidants and phosphorus-based antioxidants. The ultraviolet absorbing agent may be used to improve the light resistance of the composition of the present invention. Examples of the ultraviolet absorbing agent include benzotriazole-based ultraviolet absorbing agents and benzophenone-based ultraviolet absorbing agents. Specific examples of suitable stabilizers include SUMILIZER GM (trade name), SUMILIZER TPD (trade name) and SUMILIZER TPS (trade name) manufactured by Sumitomo Chemical Co., Ltd., IRGANOX 1010 (trade name), IRGANOX HP2225FF (trade name), IRGAFOS 168 (trade name), IRGANOX 1520 (trade name) and TINUVIN P manufactured by Ciba Specialty Chemicals, JF77 (trade name) manufactured by Johoku Chemical Co., Ltd., TOMINOX TT (trade name) manufactured by API Corporation and AO-4125 (trade name) manufactured by ADEKA CORPORATION.

Oils useful in the present invention may include unsaturated renewable oils such as sunflower oil, safflower oil, soybean oil, linseed oil, castor oil, orange oil, rapeseed oil, tall oil, vegetable processing oil, vulcanized vegetable oil, high oleic acid sunflower oil, cottonseed oil, nut oils, and combinations thereof. Useful oils may include mineral oils such as Novadex B111 or Catenex T129 (available from Shell).

Optionally, the composition may comprise a solvent. As used herein, the term “solvent” refers to a molecule or a compound that has a high vapor pressure such as greater than 2 mm Hg at 25° C. and is used to lower the viscosity of a resin but that does not have a reactive functional group capable of reacting with a functional group(s) on molecules or compounds in a composition. Suitable solvents useful in the present invention include toluene, acetone, ethyl acetate, methyl ethyl ketone, xylene, and combinations thereof.

The solvent, if present at all, may be present in the composition in an amount of at least 1% by volume based on the total volume of the composition, such as at least 2% by volume, such as at least 5% by volume, and may be present in an amount of no more than 60% by volume based on total volume of the composition, such as no more than 40% by volume, such as no more than 20% by volume. The solvent, if present at all, may be present in the composition in an amount of 1% by volume to 60% by volume based on total volume of the composition, such as 2% by volume to 40% by volume, such as 5% by volume to 20% by volume.

The composition according to the present invention may have a viscosity of at least 1 Pa·s at a shear rate of 10 s⁻¹ as measured by a MARS II rheometer at 80° C. using a cone plate with a diameter of 20 mm and an angle of 1°, such as at least 35 Pa·s, and may have a viscosity of no more than 750 Pa·s at a shear rate of 10 s⁻¹ as measured by a MARS II rheometer at 80° C. using a cone plate with a diameter of 20 mm and an angle of 1°, such as no more than 350 Pa·s. The composition according to the present invention may have a viscosity of 1 Pa·s to 750 Pa·s at a shear rate of 10 s⁻¹ as measured by a MARS II rheometer at 80° C. using a cone plate with a diameter of 20 mm and an angle of 1°, such as 35 Pa·s to 350 Pa·s.

The composition according to the present invention may have a viscosity of at least 25 Pa·s at a shear rate of 10 s⁻¹ as measured by a MARS II rheometer at 35° C. using a cone plate with a diameter of 20 mm and an angle of 1°, such as at least 50 Pa·s, and may have a viscosity of no more than 400 Pa·s at a shear rate of 10 s⁻¹ as measured by a MARS II rheometer at 35° C. using a cone plate with a diameter of 20 mm and an angle of 1°, such as no more than 115 Pa·s. The composition according to the present invention may have a viscosity of 25 Pa·s to 400 Pa·s at a shear rate of 10 s⁻¹ as measured by a MARS II rheometer at 35° C. using a cone plate with a diameter of 20 mm and an angle of 1°, such as 50 Pa·s to 115 Pa·s.

The composition according to the present invention may have a thermal conductivity of at least 0.5 W/m·K (measured according to ASTM D7984) with a TCi thermal conductivity analyzer from C-Therm Technologies Ltd., such as at least 1.0 W/m·K such as at least 1.5 W/m·K, and may have a thermal conductivity of no more than 4.0 W/m·K (measured according to ASTM D7984) with a TCi thermal conductivity analyzer from C-Therm Technologies Ltd., such as no more than 3.5 W/m·K. The composition according to the present invention may have a thermal conductivity of 0.5 W/m·K to 4.0 W/m·K (measured according to ASTM D7984) with a TCi thermal conductivity analyzer from C-Therm Technologies Ltd., such as 1.0 W/m·K to 4.0 W/m·K, such as 1.5 W/m·K to 3.5 W/m·K.

The composition according to the present invention may have a leakage current of no more than 0.5 mA/mm² (measured according to IEC 60243), such as no more than 0.1 mA/mm². The composition according to the present invention may have a leakage current of 0.03 mA/mm² to 0.5 mA/mm², such as 0.03 mA/mm² to 0.15 mA/mm².

The composition according to the present invention may have a shore 00 hardness of at least 20 (measured according to ASTM D2240, immediate 0 sec, 23° C.).

The composition may have a total solids content of at least 40% by volume based on total volume of the composition, such as at least 65%, and may have a total solids content of no more than 100% by volume based on total volume of the composition, such as no more than 95% by volume. The composition may have a total solids content of 40% to 100% by volume based on total volume of the composition, such as 40% by volume to 95% by volume. As used herein, “total solids” refers to the non-volatile content of the composition, i.e., materials which will not volatilize when heated to 105° C. and standard atmospheric pressure (101325 Pa) for 60 minutes.

The composition may be substantially free, or essentially free, or completely free, of catalyst. As used herein, the term “catalyst” means a substance that increases the rate of chemical reaction without itself undergoing any permanent chemical change. As used herein with respect to the absence of catalyst in the thermoplastic polymer, “substantially free” means that catalyst is present, if at all, in an amount of less than 0.5% by volume based on total volume of the composition. As used herein with respect to the absence of catalyst in the thermoplastic polymer, “essentially free” means that catalyst is present, if at all, in an amount of less than 0.1% by volume based on total volume of the composition. As used herein with respect to the absence of polyester in the thermoplastic polymer, “complete free” means that catalyst is not present in the composition at all, i.e., there is 0% by volume catalyst based on total volume of the composition.

The composition may be a low-VOC composition. As used herein, the term “low-VOC” refers to a composition having a theoretical VOC wt. % of less than 7% by weight, such as less than 3% by weight, such as less than 2% by weight, based on total weight of the composition. The theoretical volatile organic content (“VOC”) may be less than 105 g/L, such as less than 75 g/L, such as less than 30 g/L. As used herein,

$$VOC wt . \% = \frac{Sum of the weight of all VOC compounds}{Total Formula Weight} , and VOC ( g / L ) = \frac{VOC \% wt}{100} * Formula Density ( lb . / Galloon ) * 453.592 ( g / lb . ) * \frac{1}{3.78541 Liters / Galloon} .$$

The present invention may also be a method for preparing a one-component composition comprising, or in some cases consisting of, or in some cases consisting essentially of, a thermoplastic polymer and a thermally conductive filler package, and any of the optional further components, if used, described above, the method comprising, or in some cases consisting essentially of, or in some cases consisting of, mixing the thermoplastic polymer and the thermally conductive filler package, and any of the optional further components. The components may be mixed together in any order. The resulting one-component composition may have a thermal conductivity of at least 0.5 W/m·K (measured according to ASTM D7984) and/or a leakage current of no more than 0.5 mA/mm² (measured according to IEC 60243). The composition described above may be applied alone or as part of a system that can be deposited in a number of different ways onto a number of different substrates. The system may comprise a number of the same or different films, coatings, or layers. A film, coating, or layer is typically formed when a composition that is deposited onto at least a portion of the substrate surface through manual pressure, mechanical pressure, or extrusion.

The composition can be applied to the surface of a substrate in any number of different ways, non-limiting examples of which include brushes, rollers, films, pellets, trowels, spatulas, dips, spray guns and applicator guns to form a coating on at least a portion of the substrate surface. Alternatively, the composition may be casted, extruded, moulded, or machined to form a part or a member.

The present invention also is directed to a method for treating a substrate comprising, or consisting essentially of, or consisting of, contacting at least a portion of a surface of the substrate with one of the compositions of the present invention described hereinabove. The coating, layer or film, may be, for example, a sealant, a gap filler, or an adhesive.

The present invention is also directed to a method for forming a bond between two substrates for a wide variety of potential applications in which the bond between the substrates provides particular mechanical properties related to lap shear or peel strength. The method may comprise, or consist essentially of, or consist of, applying the composition described above to a first substrate; contacting a second substrate to the composition such that the composition is located between the first substrate and the second substrate; and applying sufficient pressure for the composition to intimately contact both substrates. For example, the composition may be applied to either one or both of the substrate materials being bonded to form an adhesive bond there between and the substrates may be aligned and pressure and/or spacers may be added to control bond thickness. The composition may be applied to cleaned or uncleaned (i.e., including oily or oiled) substrate surfaces.

As stated above, the composition of the present disclosure also may form a sealant on a substrate or a substrate surface. The sealant composition may be applied to substrate surfaces, including, by way of non-limiting example, a vehicle body or components of a vehicle or airplane, a battery, or a circuit board. The sealant formed by the composition of the present invention provides sufficient thermal conductivity and seals unwanted elements (i.e. dust, moisture, air) out of the substrate. The sealant composition may be applied to cleaned or uncleaned (i.e., including oily or oiled) substrate surfaces. It may also be applied to a substrate that has been pretreated, coated with an electrodepositable coating, coated with additional layers such as a primer, basecoat, or topcoat.

The substrates that may be coated by the compositions of the present invention are not limited. Suitable substrates useful in the present invention include, but are not limited to, materials such as metals or metal alloys, polymeric materials such as hard plastics including filled and unfilled thermoplastic materials or thermoset materials, or composite materials. Other suitable substrates useful in the present invention include, but are not limited to, glass or natural materials such as wood. For example, suitable substrates include rigid metal substrates such as ferrous metals, aluminum, aluminum alloys, magnesium titanium, copper, and other metal and alloy substrates. The ferrous metal substrates used in the practice of the present invention may include iron, steel, and alloys thereof. Non-limiting examples of useful steel materials include cold rolled steel, galvanized (zinc coated) steel, electrogalvanized steel, stainless steel, pickled steel, zinc-iron alloy such as GALVANNEAL, and combinations thereof. Combinations or composites of ferrous and non-ferrous metals can also be used. Aluminum alloys of the 1XXX, 2XXX, 3XXX, 4XXX, 5XXX, 6XXX, 7XXX, or 8XXX series as well as clad aluminum alloys and cast aluminum alloys of the A356, 1XX.X, 2XX.X, 3XX.X, 4XX.X, 5XX.X, 6XX.X, 7XX.X, or 8XX.X series also may be used as the substrate. Magnesium alloys of the AZ31B, AZ91C, AM60B, or EV31A series also may be used as the substrate. The substrate used in the present invention may also comprise titanium and/or titanium alloys of grades 1-36 including H grade variants. Other suitable non-ferrous metals include copper and magnesium, as well as alloys of these materials. Suitable substrates for use in the present invention include those that are used in the assembly of vehicles, batteries, and electronics. For example, suitable substrates include without limitation vehicular battery, vehicular door, body panels, trunk deck lid, roof panel, hood, roof and/or stringers, rivets, landing gear components, and/or skins used on an aircraft), a vehicular frame, vehicular parts, motorcycles, and industrial structures and components. As used herein, “vehicle” or variations thereof includes, but is not limited to, civilian, commercial and military aircraft, and/or land vehicles such as cars, motorcycles, and/or trucks. The metal substrate also may be in the form of, for example, a sheet of metal or a fabricated part. It will also be understood that the substrate may be pretreated with a pretreatment solution including a zinc phosphate pretreatment solution such as, for example, those described in U.S. Pat. Nos. 4,793,867 and 5,588,989, or a zirconium containing pretreatment solution such as, for example, those described in U.S. Pat. Nos. 7,749,368 and 8,673,091. The substrate may be coated, such as with a primer or paint, such as an electrodeposited primer coating. The substrate may comprise a composite material such as a plastic or a fiberglass composite. The substrate may be a fiberglass and/or carbon fiber composite. The compositions of the present invention are particularly suitable for use in various industrial or transportation applications including automotive, light and heavy commercial vehicles, marine, or aerospace.

The composition of the present invention also may be used to produce articles, using three-dimensional printing. A three-dimensional article may be produced by forming successive portions or layers of an article by depositing a composition of the present invention onto a substrate and thereafter depositing additional portions or layers of the composition over the underlying deposited portion or layer and/or adjacent the previously deposited portion or layer. Layers can be successively deposited adjacent a previously deposited layer to build a printed article. A composition can be mixed and then deposited. By “portions of an article” is meant subunits of an article, such as layers of an article. The layers may be on successive horizontal parallel planes. The portions may be parallel planes of the deposited material or beads of the deposited material produced as discreet droplets or as a continuous stream of material. The components of the composition may each be provided neat or may also include a solvent (organic and/or water) and/or other additives as described herein. The composition of the present invention can be deposited using any suitable equipment. The selection of suitable deposition equipment depends on a number of factors including the deposition volume, the viscosity of the composition and the complexity of the part being fabricated. The composition can be pushed under pressure or extruded through the nozzle. The composition may be injected or otherwise placed in a die caster or a mould to form a part or a member and optionally may be machined to a particular configuration.

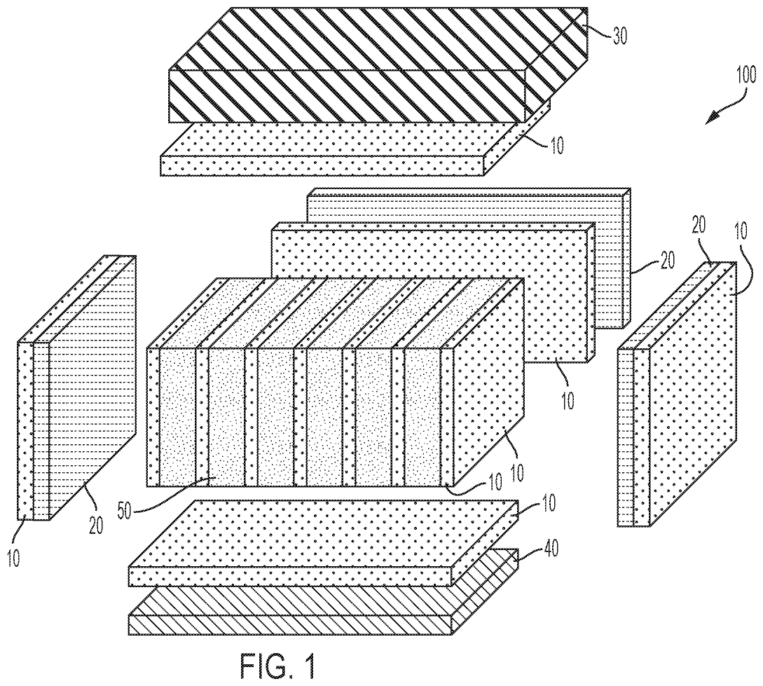

FIG. 1 is a schematic perspective view illustrating a thermally conductive member utilized as a gap filler in a battery pack 100. In the example illustrated, the thermally conductive matter 10 (formed from the compositions described herein) is positioned between two battery cells/battery modules 50 which are interconnected in series or in parallel by interconnects (not shown). The thermally conductive matter 10 also may be positioned between a cooling fin 30 and/or a battery cell/battery module 50, between battery modules 50, between a cooling plate 40 and a battery cell/battery module 50, between a battery cell/battery module 50 and a surface of a wall of a battery box 20, or may be applied as a coating on at least a portion of the substrate of a wall of a battery box 20. The battery pack may further comprise a thermal management system (not shown) comprising air or fluid circuits, which may be liquid based (for example glycol solutions) or direct refrigerant based.

Whereas specific aspects of the invention have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of the invention which is to be given the full breadth of the claims appended and any and all equivalents thereof.

### Aspects

In view of the foregoing the present invention thus relates inter alia, without being limited thereto, to the following aspects:

Aspect 1. A composition, comprising:

a thermoplastic polymer; and

a thermally conductive filler package comprising thermally conductive, electrically insulative filler particles having a thermal conductivity of at least 5 W/m·K (measured according to ASTM D7984) and a volume resistivity of at least 10 Ω·m (measured according to ASTM D257, C611, or B193) and present in an amount of at least 50% by volume based on total volume of the filler package.

Aspect 2. The composition of Aspect 1, wherein the composition has a thermal conductivity of at least 0.5 W/m·K measured at 20° C. and a leakage current of less than 0.5 mA/mm² (measured according to IEC 60243).

Aspect 3. The composition of Aspect 1 or Aspect 2, wherein the thermoplastic polymer is present in an amount of 1% by volume to 80% by volume based on total volume of the composition.

Aspect 4. The composition of any of the preceding Aspects, wherein the thermoplastic polymer comprises polybutadiene, polyisobutylene, polybutene, or combinations thereof.

Aspect 5. The composition of any of the preceding Aspects, wherein the thermoplastic polymer is substantially free of reactive functional groups.

Aspect 6. The composition of any of the preceding Aspects, wherein the thermoplastic polymer comprises an elastomeric material.

Aspect 7. The composition of any of the preceding Aspects, wherein the thermoplastic polymer is substantially free of silicone.

Aspect 8. The composition of any of the preceding Aspects, wherein the filler package is present in an amount of 20% by volume to 99% by volume based on total volume of the composition.

Aspect 9. The composition of any of the preceding Aspects, wherein the filler package further comprises thermally conductive, electrically conductive filler particles having a thermal conductivity of at least 5 W/m·K (measured according to ASTM 7984) and a volume resistivity of less than 1 Ω·m (measured according to ASTM D257, C611, or B193).

Aspect 10. The composition of Aspect 9, wherein the thermally conductive, electrically conductive filler particles are present in an amount of no more than 50% by volume based on total volume of the filler package.

Aspect 11. The composition of any of the preceding Aspects, wherein the filler package further comprises non-thermally conductive, electrically insulative filler particles having a thermal conductivity of less than 5 W/m·K (measured according to ASTM 7984) and a volume resistivity of at least 1 Ω·m (measured according to ASTM D257, C611, or B193).

Aspect 12. The composition of Aspect 11, wherein the non-thermally conductive, electrically insulative filler particles are present in an amount of no more than 10% by volume based on total volume of the filler package.

Aspect 13. The composition of any of the preceding Aspects wherein at least one of the thermally conductive fillers of the filler package comprises a surface treated filler particle.

Aspect 14. The composition of any of the preceding Aspects, further comprising an additive.

Aspect 15. The composition of any of the preceding Aspects, wherein the composition has a viscosity of 1 Pa·s to 700 Pa·s at a shear rate of 10 s⁻¹ as measured by an MARS II rheometer at 80° C. using a cone plate with a diameter of 20 mm and an angle 1°.

Aspect 16. The composition of any of the preceding Aspects, wherein the composition comprises a total solids content of 40% by volume to 100% by volume based on total weight of the composition.

Aspect 17. The composition of any of the preceding Aspects, further comprising a dispersant.

Aspect 18. The composition of Aspect 17, wherein the dispersant is present in an amount of 0.05% by volume to 20% by volume based on total volume of the composition.

Aspect 19. The composition of any of the preceding Aspects, wherein the coating composition comprises a gap filler composition, a sealant composition, a 3D printable composition, a putty, a molding compound, a potting compound, and/or an adhesive composition.

Aspect 20. The composition of any of the preceding Aspects, wherein the composition is a one-component composition.

Aspect 21. A coating, comprising a thermal conductivity of at least 0.5 W/m·K (measured according to ASTM D7984) and a leakage current of less than 0.5 mA/mm² (measured according to IEC 60243).

Aspect 22. The coating of Aspect 21, formed from the composition of any of Aspects 1 to 20.

Aspect 23. A coated substrate comprising a surface, at least a portion of which is coated with a coating formed by the composition of any of Aspects 1 to 20.

Aspect 24. The coated substrate of Aspect 23, wherein the coating has:
(a) a thermal conductivity of at least 0.5 W/m·K (measured according to ASTM D7984); and/or
(b) a leakage current of less than 0.5 mA/mm² (measured according to IEC 60243).

Aspect 25. A battery assembly comprising the coating of Aspect 21 or Aspect 22 or the coated substrate of Aspect 23 or Aspect 24.

Aspect 26. A circuit board comprising the coating of Aspect 21 or Aspect 22 or the coated substrate of Aspect 23 or Aspect 24.

Aspect 27. A part comprising the coating of Aspect 21 or Aspect 22 or the coated substrate of Aspect 23 or Aspect 24.

Aspect 28. A substrate comprising the coating of Aspect 21 or Aspect 22 or the coated substrate of Aspect 23 or Aspect 24.

Aspect 29. A method of forming a coating on a substrate surface comprising applying the composition of any of Aspects 1-20 to a surface of a first substrate.

Aspect 30. The method of Aspect 29, further comprising contacting a surface of a second substrate to the composition such that the composition is located between the first substrate and the second substrate.

Aspect 31. A method of forming an article comprising extruding the composition of any of Aspects 1 to 20.

Aspect 32. The method of Aspect 31, wherein the extruding comprises three-dimensional printing.

Aspect 33. The article formed by the method of Aspect 31 or Aspect 32.

Illustrating the invention are the following examples, which, however, are not to be considered as limiting the invention to their details. Unless otherwise indicated, all parts and percentages in the following examples, as well as throughout the specification, are by volume.

### Examples

TABLE 1
Abbreviation description of materials used in Examples 1 to 6

| | | | | Molec- |
|---|---|---|---|---|
| | | | | ular |
| RAW | Commercial | | D50 | Weight |
| MATERIAL | name | Supplier | (μm) | (g/mol) |
| ATH | FRAT 44 | ALTEO | 22 | — |
| (aluminum | | (UNIVAR | | |
| trihydrate) | | distributor) | | |
| (TC/EI filler) | | | | |
| Calcinated | P122SB | ALTEO | 2.2 | — |
| Alumina | | (UNIVAR | | |
| (TC/EI filler) | | distributor) | | |
| Aluminum | APYRAL 20X | Nabaltec | 8 | — |
| trihydrate | | | | |
| (TC/EI filler) | | | | |
| ZnO | ZNO RAC | Bruggeman | 50 | — |
| (TC/EI filler) | | (Brenntag | | |
| | | distributor) | | |
| MgO (spherical) | DENKA-MgO | DENKA | 105 | — |
| (TC/EI filler) | | | | |
| Calcinated Kaolin | Polestar 200R | IMERIS | — | — |
| (NTC/EI filler) | | (SMPC | | |
| | | distributor) | | |
| Kaolin (NTC/EI) | Kaolin G3G | BASSERMANN | — | — |
| Polyisobutylene | OPPANOL B10 | BASF | — | 40000 |
| (thermoplastic | | | | |
| polymer) | | | | |
| Polyisobutylene | OPPANOL B12 | BASF | — | 55000 |
| (thermoplastic | | | | |
| polymer) | | | | |
| Polyisobutylene | INDOPOL H100 | INEOS | — | 910 |
| (thermoplastic | | | | |
| polymer) | | | | |
| Dioctyl adipate | Cereplast DOA | valtris (CALDIC | — | — |
| (DOA) | | distributor) | | |
| Saturated oil | novadex B111 | MULTISOL | — | — |
| (Additive) | | | | |
| Pigmen | EUROPHTAL | QUADRIMEX | — | — |
| (colorant) | BLUE 2103 | | | |
| Pigment | Bleu | NUBIOLA | — | — |
| (colorant) | Ultramarine | | | |
| Dispersant | DRAPEX 39 | GALATA | — | — |
| | | CHEMICALS | | |
| Dispersant | ANTI TERRA | BYK | — | — |
| | U100 | | | |

TABLE 2
Thermal conductivity, viscosities, and leakage
current of compositions of Examples 1 to 6

| Composition | Ex 1 | Ex 2 | Ex 3 | Ex 4 | Ex 5 | Ex 6 |
|---|---|---|---|---|---|---|
| FRAT 44 | 53.55 | 55.47 | 58.12 | 56.34 | 71.44 | — |
| APYRAL 20X | — | — | — | — | — | 71.87 |
| P122SB | — | — | — | 10.48 | — | — |
| DENKA | — | 11.87 | — | — | — | — |
| Polestar 200R | 14.92 | — | — | — | — | — |
| ZNO RAC | — | — | 7.65 | — | — | — |
| Kaolin G3G | — | — | — | — | 2.33 | — |
| OPPANOL B10 | — | — | — | — | 10.09 | — |
| OPPANOL B12 | 10.63 | 11.01 | 11.54 | 11.18 | — | — |
| INDOPOL H100 | 3.27 | 3.39 | 3.55 | 3.44 | — | 14.78 |
| CEREPLAS DOA | 11.76 | 12.18 | 12.76 | 12.37 | 5.45 | — |
| Novadex B111 | — | — | — | — | 5.87 | — |
| ANTI TERRA U100 | 5.87 | 6.08 | 6.37 | 6.18 | 4.79 | — |
| Bleu Ultramarine | — | — | — | — | — | 0.45 |
| Drapex 39 | — | — | — | — | — | 12.91 |
| EUROPHTAL | — | — | — | — | 0.03 | — |
| BLUE 2103 | | | | | | |
| TC (W/mK) | 1.95 | 3 | 2.4 | 2.8 | 2.8 | 3.3 |
| Viscosity | 320.8 | 51.13 | 350.23 | 112.83 | 40.73 | 91.76 |
| (Pa · s) @ 35° C. | | | | | | |
| Viscosity | 58.21 | 44.04 | 111.4 | 41.31 | 40 | 42.16 |
| (Pa · s) @ 80° C. | | | | | | |
| Leakage Current | 0.21 | 0.09 | 0.05 | 0.24 | 0.09 | 0.04 |
| (mA/mm²) | | | | | | |

The compositions of Examples 1-6 were prepared using the ingredients shown in Table 2 according to the following procedure with all non-manual mixing performed using a Z-blade mixer (Marc Guittard). For each example, all raw materials were put together and mixing at speed 50 tr/min for 20 minutes, and then mixed for additional 20 minutes.

The compositions of Examples 1-6 were tested for thermal conductivity at room temperature using a Modified Transient Plane Source (MTPS) method (measured according to ASTM D7984) with a TCi thermal conductivity analyzer from C-Therm Technologies Ltd. The sample was manually transferred onto the sensor at ambient conditions. The sample size was at least 30 mm by 30 mm with a thickness of 20 mm. Data are reported in Table 2. As shown, each experimental sample had a thermal conductivity of at least 1.0 W/mK.

Viscosity was measured using an MARS II rheometer at 35° C. or 80° C., using a mobile (20/1) with a diameter 20 mm and an angle 1°. The sample was compressed to a thickness of 0.3 mm. Excess material was removed prior to measuring viscosity. The gap was set to be 0.3 mm. Shear rate program was: (1) Linear ramp up 0-10/s in 120 s; (2) Hold speed at 10/s during 120 s; (3) Linear ramp down 10-0/s in 120 s. Data are reported in Table 2. As shown, viscosity of the experimental samples was 40 Pa·s at 80° C. to 120 Pa·s at 80° C.

Leakage current was measured according to IEC 60243 standard on a SEFELEC SXS56, Electronical safety tester 50 VA (Eaton) at room temperature. 3 g of sample was manually loaded in between the steel cover and the aluminum substrate. The sample was compressed to a thickness of 0.2 mm. The diameter of the sample (D) was measured by a steel ruler and the surface area (AR) of the sample was calculated using the equation π(D/2)². The applied voltage was 2.5 kV and the current of each sample (I) was recorded after the voltage was stabilized for 60 seconds. The leakage current was obtained by I(i)=FAR. Data are reported in Table 2. The leakage current of the samples were less than 0.5 mA/mm².

It will be appreciated by skilled artisans that numerous modifications and variations are possible in light of the above disclosure without departing from the broad inventive concepts described and exemplified herein. Accordingly, it is therefore to be understood that the foregoing disclosure is merely illustrative of various exemplary aspects of this application and that numerous modifications and variations can be readily made by skilled artisans which are within the spirit and scope of this application and the accompanying claims.

1. A composition, comprising:
a thermoplastic polymer; and
a thermally conductive filler package comprising thermally conductive, electrically insulative filler particles having a thermal conductivity of at least 5 W/m·K (measured according to ASTM D7984) and a volume resistivity of at least 10 Ω·m (measured according to ASTM D257, C611, or B193) and present in an amount of at least 50% by volume based on total volume of the filler package.

2. The composition of claim 1, wherein the composition has a thermal conductivity of at least 0.5 W/m·K (measured according to ASTM D7984) and a leakage current of less than 0.5 mA/mm² (measured according to IEC 60243).

3. The composition of claim 1, wherein the thermoplastic polymer is present in an amount of 1% by volume to 70% by volume based on total volume of the composition.

4. The composition of claim 1, wherein the thermoplastic polymer comprises an elastomeric material.

5. The composition of claim 1, wherein the thermoplastic polymer is substantially free of silicone.

6. The composition of claim 1, wherein the filler package is present in an amount of 30% by volume to 99% by volume based on total volume of the composition.

7. The composition of claim 1, wherein the filler package further comprises (i) thermally conductive, electrically conductive filler particles having a thermal conductivity of at least 5 W/m·K (measured according to ASTM 7984) and a volume resistivity of less than 1 Ω·m (measured according to ASTM D257, C611, or B193) and present in an amount of no more than 50% by volume based on total volume of the filler package, and/or (ii) non-thermally conductive, electrically insulative filler particles having a thermal conductivity of less than 5 W/m·K (measured according to ASTM 7984) and a volume resistivity of at least 1 Ω·m (measured according to ASTM D257, C611, or B193) and present in an amount of no more than 10% by volume based on total volume of the filler package.

8. (canceled)

9. The composition of claim 1, wherein the composition has a viscosity of 1 Pa·s to 700 Pa·s at a shear rate of 10 s⁻ as measured by an MARS II rheometer at 80° C. using a cone plate with a diameter of 20 mm and an angle 1° and/or wherein the composition comprises a total solids content of 40% by volume to 100% by volume based on total volume of the composition.

10. (canceled)

11. The composition of claim 1, wherein the composition further comprises a dispersant and/or an additive.

12. The composition of claim 11, wherein the dispersant is present in an amount of 0.01% by volume to 20% by volume based on total volume of the composition.

13. (canceled)

14. The composition of claim 1, wherein the coating composition comprises a gap filler composition, a sealant composition, a 3D printable composition, a putty, a molding compound, a potting compound, and/or an adhesive composition.

15. A coating, comprising a thermal conductivity of at least 0.5 W/m·K (measured according to ASTM D7984) and a leakage current of less than 0.5 mA/mm² (measured according to IEC 60243).

16. The coating of claim 15, formed from the coating composition of claim 1.

17. A substrate comprising a surface, at least a portion of which is coated with the coating of claim 15.

18. A battery assembly comprising the substrate of claim 17.

19. A circuit board comprising the substrate of claim 17.

20. A part comprising the substrate of claim 17.

21. An article comprising the substrate of claim 17.

22. A method of forming a coating on a substrate surface comprising:
applying the composition of claim 1 to a surface of the substrate such that at least a portion of the surface is coated with the composition.

23. A method of forming an article comprising extruding the composition of claim 1.

24. The method of claim 23, wherein the extruding comprises three-dimensional printing.

25. The article formed by the method of claim 23.
